(19) United States
(12) Patent Application Publication
(10) Pub. No.: US 2023/0230651 A1
(43) Pub. Date: Jul. 20, 2023

(54) METHOD AND DEVICE FOR TESTING MEMORY CHIP, STORAGE MEDIUM AND ELECTRONIC DEVICE

(71) Applicant: CHANGXIN MEMORY TECHNOLOGIES, INC., Hefei City (CN)

(72) Inventor: Dong LIU, Hefei (CN)

(21) Appl. No.: 17/854,257

(22) Filed: Jun. 30, 2022

Related U.S. Application Data
(63) Continuation of application No. PCT/CN2022/080237, filed on Mar. 10, 2022.

(30) Foreign Application Priority Data
Jan. 19, 2022 (CN) 202210061031.2

(51) Int. Cl. G11C 29/44

(52) U.S. Cl. CPC G11C 29/44

(57) ABSTRACT

A method and a device for testing a memory chip, a computer-readable storage medium and an electronic device are provided. The method for testing a memory chip includes the following operations. Test data is written into memory cells of the memory chip based on a target write time of the memory chip. Memory data is read from the memory cell based on a target read time of the memory chip (S110). A test result of the memory chip is determined based on the test data and the memory data (S120). The test data includes multiple different binary sequences, only one of data bits in each binary sequence is 1, the target write time is less than a standard write time of the memory chip, and the target read time is less than a standard read time of the memory chip.

### CROSS-REFERENCE TO RELATED APPLICATION

The disclosure is a continuation of International Application No. PCT/CN2022/080237, filed on Mar. 10, 2022, which claims priority to Chinese patent application No. 202210061031.2, filed on Jan. 19, 2022. The contents of International Application No. PCT/CN2022/080237 and Chinese patent application No. 202210061031.2 are hereby incorporated by reference in their entireties.

### BACKGROUND

As an important part of a digital chip, a memory chip can store programs and various data, and can access the programs or data automatically at high speed during an operation of computer.

Before the memory chip is put into use, the memory chip is required to be tested by a technician to verify the performance of the memory chip. According to a method for testing a memory chip in the related art, the performance of the memory chip is determined by traversing each memory cell of the memory chip and implementing read-write operations on each memory cell according to corresponding read-write rules. In this way, however, test time of the memory chip should meet writing time, reading time, communication time, programming time, etc., of each memory cell. To complete the detection on each memory cell, the test time is often longer than the actual test time. In a mass production test, a test process consumes a lot of time, and the test efficiency is low, which makes it difficult to meet production demands of the memory chips.

### SUMMARY

The disclosure relates to the technical field of integrated circuits, and in particular to a method and a device for testing a memory chip, a computer-readable storage medium and an electronic device.

In a first aspect, the disclosure provides a method for testing a memory chip, including the following operations. Test data is written into memory cells of the memory chip based on a target write time of the memory chip. Memory data is read from the memory cell based on a target read time of the memory chip. A test result of the memory chip is determined based on the test data and the memory data. The test data includes multiple different binary sequences, only one of data bits in each binary sequence is 1, the target write time is less than a standard write time of the memory chip, and the target read time is less than a standard read time of the memory chip.

In a second aspect, the disclosure provides a device for testing a memory chip, including a data module and a determination module. The data module is configured to write test data into memory cells of the memory chip based on a target write time of the memory chip, and read memory data from the memory cell based on a target read time of the memory chip. The determination module is configured to determine a test result of the memory chip based on the test data and the memory data. The test data includes multiple different binary sequences, only one of data bits in each binary sequence is 1, the target write time is less than a standard write time of the memory chip, and the target read time is less than a standard read time of the memory chip.

In a third aspect, the disclosure provides a non-transitory computer-readable storage medium having a computer program stored thereon, and the computer program is configured to perform the method for testing the memory chip in the first aspect, when executed by a processor.

In a fourth aspect, the disclosure provides an electronic device, including a processor and a memory configured to store processor-executable instructions. The processor is configured to execute the executable instructions to perform the method for testing the memory chip in the first aspect.

The technical solution of the disclosure may include the following advantages.

It should be understood that, the foregoing general description and the following detailed description are merely illustrative and are not intended to limit the disclosure.

### BRIEF DESCRIPTION OF THE DRAWINGS

The accompanying drawings which are incorporated in and constitute a part of the specification illustrate embodiments of the disclosure, and serve to explain principles of the disclosure together with the specification. It is apparent that the drawings described below merely illustrate some embodiments of the disclosure, and other drawings may be derived therefrom by those of ordinary skill in the art without making creative efforts.

FIG. 1 illustrates a flowchart of a method for testing a memory chip in an exemplary implementation.

FIG. 2 illustrates an example of test data in an exemplary implementation.

FIG. 3A and FIG. 3B illustrate an example of testing a memory chip in an exemplary implementation.

FIG. 4 illustrates a flowchart of another method for testing a memory chip in an exemplary implementation.

FIG. 5 illustrates a structural block diagram of a device for testing a memory chip in an exemplary implementation.

FIG. 6 illustrates a schematic diagram of a computer-readable storage medium configured to implement a method for testing a memory chip in an exemplary implementation.

FIG. 7 illustrates a schematic diagram of an electronic device configured to implement a method for testing a memory chip in an exemplary implementation.

### DETAILED DESCRIPTION

Exemplary embodiments will now be described more comprehensively with reference to the drawings. The exemplary embodiments, however, may be implemented in different ways and should not been constructed as being limited to the examples set forth herein. Rather, the embodiments are provided to make the disclosure more comprehensive and complete, and convey the principles of the exemplary embodiments in their entirety to those skilled in the art. Same reference numerals in the drawings designate same or similar structures, and thus their detailed description will not be repeated herein.

Although relative terms, such as “up” and “down”, are used in the specification to describe the relative relation of a component to another in the drawings, the terms are used in the specification for convenience only, such as, the terms are used based on the directions of the examples shown in the drawings. It should be understood that, if a device is flipped over, a component designated with “top” will become a component designated with “bottom”. The same thing is true with other relative terms, such as “high”, “low”, “top”, “bottom”, “left” and “right.” When a structure is “on” another structure, it may means that the structure is integrally formed on another structure, or that the structure may be “directly” arranged on another structure, or that the structure is “indirectly” arranged on another structure through a structure.

Terms “one”, “a/an” and “the” are used to denote one or more elements/components/etc. Terms “including”, “comprising” and “having” are used to denote covering on a non-exclusive basis and that additional elements/components/etc. may exist in addition to the listed elements/components/etc.

The test of the memory chip is of great significance to ensure the long-term and reliable use of the chip. Therefore, the memory chip is required to be tested at high speed and carefully by an enterprise before the memory chip is out of the factory. For each kind of memory chip, the change of each memory cell may affect the change of another cell in the memory. This correlation leads to a very complicated problem in the test of the memory chips; therefore, it is impossible to draw a conclusion merely by sequentially testing each memory cell of the memory chip.

Based on the foregoing problems, an exemplary implementation of the disclosure provides a method for testing a memory chip. According to the method, the test data is sequentially written into each memory cell of the memory chip, and the test result of the memory chip is determined based on a read result of the test data written each time. In an exemplary implementation, the memory chip may be a dynamic random access memory (DRAM).

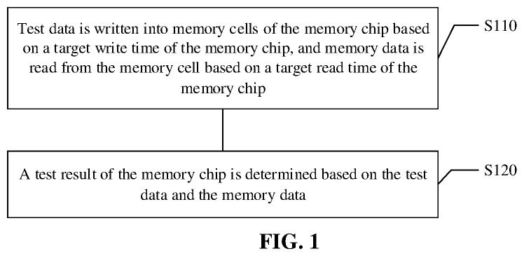

FIG. 1 illustrates a flowchart of a method for testing a memory chip in an exemplary implementation, which may include the following operations S110 to S120.

At S110, test data is written into memory cells of the memory chip based on a target write time of the memory chip, and memory data is read from the memory cell based on a target read time of the memory chip.

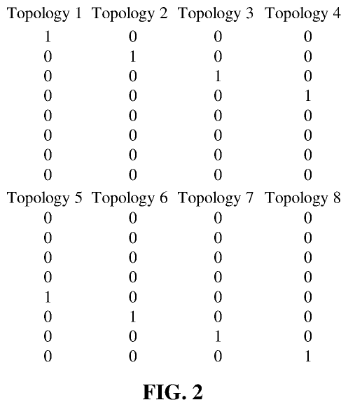

The target write time is less than a standard write time of the memory chip, and the target read time is less than a standard read time of the memory chip. The standard write time refers to write recovery time of the memory chip, i.e., time duration between a write command issued or a start of writing and a next precharge of the memory chip. The standard read time refers to random access storage (RAS) precharge time, i.e., time required for the memory chip to prepare for a next row address operation in a same logic bank after the previous row address operation has been completed and after a row address off command has been issued. The memory cell is a unit with a function of storing data and reading and writing data in the memory chip. Each memory cell includes an etched transistor and a capacitor. The etched transistor is in a storage state through charges of the capacitor. The test data may be configured to test the memory cell of the memory chip. Due to the fact that the memory chip represents and stores data in binary, exemplarily, the test data may include multiple different binary sequences, only one of data bits in each binary sequence is “1”. For example, for multiple forms of test data shown in FIG. 2, when the test data is 8-bit data, the test data includes 8 binary sequences, each of which is a data topology. Generally, a sequence length of the test data is less than or equal to a number of memory cells of the memory chip. The memory data refers to data obtained by reading the written test data from the memory cell of the memory chip, which may be configured to verify the read-write performance of the memory cell.

When a memory chip is tested, test data may be written into the memory cells of the memory chip. For example, a binary sequence in the test data may be sequentially written into each memory cell of the memory chip, binary data in each binary sequence is written into each memory cell of the memory chip, therefore, 1-bit data, i.e., “0” or “1” is written into each memory cell, and then the written test data may be read from each memory cell of the memory chip to obtain the memory data in each memory cell, i.e., the memory data of the memory chip.

Specifically, when writing the test data, the target write time may be set through a logic control circuit. A capacitor in a memory cell may be configured to periodically apply a specific input signal, so as to write test data into the memory cell of the memory chip. The writing of the test data into each memory cell of the memory chip is completed, so that 1-bit binary data is written into each memory cell. When reading the test data, the memory chip may be controlled by the logic control circuit to complete precharge of a next memory cell during clock time corresponding to the target read time, and then read the test data of the next memory cell to obtain the test data written into the memory cell and obtain the memory data. The timing of the memory chip refers to a clock cycle value. A pulse signal rises and then falls, and a cycle of a rise and fall before a next rise is defined as a clock cycle. As the frequency of the memory chip increases, the clock cycle will become shorter. In an exemplary implementation, a clock signal of a memory chip may be a square wave signal, and a memory chip performs data transmission once during each rise and each fall of the clock signal. Therefore, when the memory chip writes and reads the test data, the logic control circuit may be configured to control the clock signal based on the target write time and the target read time to generate a pulse signal based on corresponding clock cycle, and control a memory cell of the memory chip to write-read the test data based on a corresponding write-read cycle to obtain the memory data.

In an alternative implementation, the test data may be any of multiple different binary sequences. In this manner, any binary sequence may be written into the memory cells of the memory chip based on the target write time of the memory chip, so that 1-bit data is written into each memory cell, and the memory data is read from each memory cell based on a target read time of the memory chip.

Further, in an alternative implementation, to facilitate writing test data into the memory cells, the test data may be the binary sequences with equal data bits and the test data has different data topologies. A data topology may be configured to represent a data structure of a binary sequence written into a memory cell in each test period, the test data written into the memory cell during each test period may be the same, the test data written into the memory cell during different test periods are different, and different test data has different data topologies. The test period refers to a time period during which the test data is written into all memory cell of the memory chip at one time.

Memory cells in the memory chip may be distributed into corresponding memory arrays. Therefore, the test data may be written in order of rows or columns of memory cells, and a data bit length of the test data written into each row or column of memory cells is equal. During each test period, same test data may be written into all memory cells of the memory chip. For example, assuming that the length of test data is equal to the number of columns of the memory cells of the memory chip, the test data may be written into each row of memory cells, so that 1-bit binary data is written into each row of memory cells, at this time, same binary data is written into a same column of memory cells.

In an alternative implementation, for test data having different data topologies, the multiple data topologies in the test data may be determined through the following operations.

The initial test data is traversed by taking any of data bits in the initial test data as a conversion bit, and the data at the traversed conversion bit is converted into the inverted data to obtain a conversed sequence, until all the data bits in the initial test data are traversed, and the obtained multiple conversed sequences are determined as the multiple data topologies. The initial test data may be an all-0 sequence of any length.

For example, assuming that the initial test data is “00000000”, a first data bit in the initial test data is taken as a conversion bit, data at the conversion bit is converted into inverted data to obtain a first conversed sequence “10000000”, then a second data bit is taken as a conversion bit, data at the conversion bit in the initial test data is converted into inverted data to obtain a second conversed sequence “01000000”, and a third data bit is taken as a conversion bit, etc., until a last data bit in the initial test data is taken as a conversion bit, and data at the conversion bit is converted into inverted data to obtain a last conversed sequence, and all the conversed sequences form the multiple different data topologies.

In this manner, the multiple conversed sequences may be obtained based on the conversed initial test data. During test, each sequence in the initial test data and the test data including the conversed sequences may be written into all memory cells of the memory chip, and each time after writing data into all memory cells, the data written into the memory cells is read to obtain the memory data.

At S120, a test result of the memory chip is determined based on the test data and the memory data.

The test data is compared with the memory data to determine whether the data read from each memory cell of the memory chip is the same as the data written into the memory cell, and the test result of the memory chip is obtained. The test result may be configured to indicate whether the read-write performance of each memory cell of the memory chip is abnormal.

Specifically, in an alternative implementation, the test result may be obtained by comparing the memory data with the test data. The test result may indicate whether a read-write error occurs in each of the memory cells of a memory chip and may indicate a number of data bits with the read-write error.

For example, the memory data read from each of memory cells is compared with the test data written into the memory cell based on a direction in which the test data is written, and it is determined whether the data read from each of the memory cells is the same as the data written into the memory cell. If the data read from the memory cell is not the same as the data written into the memory cell, it may be determined that a read-write error occurs in the memory cell, and a data bit in which the memory cell is positioned is the data bit with a read-write error occurs. If the data read from each of the memory cells is the same as the data written into the memory cell, it may be determined that no read-write error occurs in the memory cell. Therefore, the test result of each memory cell of the memory chip may be obtained.

In this manner, the test data may be written into memory cells of the memory chip, and the data written into the memory cell is read to obtain the memory data. The memory cell with a read-write error of the memory chip and the bit of the memory cell with a read-write error is determined based on a difference between the memory data and the test data, thereby completing the test of the memory chip. Meanwhile, due to the fact that the target write time is less than the standard write time for the memory chip to perform the writing operation and the target read time is less than the standard read time for the memory chip to perform the reading operation, an insufficient time condition can be created for reading and writing of the memory chip by reducing a timing value, and the efficiency of detecting the memory cell with abnormal reading and writing of the memory chip is improved, that is, the efficiency of testing the memory chip is improved.

In a DRAM chip, data is stored through capacitor. Due to inherent properties of the capacitor, information will be gradually lost with changes of time and temperature.

Therefore, in an alternative implementation, to prevent loss of information in the memory cell and to ensure continuous storage of second test data in the memory chip, after determining the test result of the memory chip, all the memory cells of the memory chip may also be set to 0. Specifically, a binary sequence of all-0 may be written into each memory cell of the memory chip, i.e., 1-bit binary data “0” may be written into each memory cell of the memory chip, until the data is written into all the memory cells of the memory chip. In this manner, the storage of the data written into the memory cells may be maintained, the accuracy of testing other memory cells can be improved, which is convenient for a next test on the memory chip.

As described above, the memory cells of the memory chip are generally arranged in arrays. To facilitate the testing of the memory chip, corresponding test data may be written in order of rows or columns in which the memory cells are positioned. Therefore, in an alternative implementation, test data may be written into each row of memory cells of the memory chip in a form of traversal access, and the memory data can be read from each row of memory cells of the memory chip. For example, test data may be written into each row of memory cells of the memory chip in order of rows of an array in which the memory cells are positioned, such as sequentially writing 1-bit binary data into each memory cell in each row, until each memory cell of the memory chip is written with the test data.

Further, in an alternative implementation, the method for testing the memory chip may further include the following operations.

During a row detection period, the test data is writing into any row of memory cells of the memory chip, and the memory data is read from the any row of memory cells.

Test results of the any row of memory cells are determined based on the test data written into the any row of memory cells and the memory data read from the any row of memory cells.

The row detection period refers to time duration required for testing a row of memory cells. When the test data is written in order of rows, during the row detection period, the test data may be written into any row of memory cells of the memory chip, and after writing the data into the row of memory cells, the data stored in the row of memory cells is read to obtain the memory data, and the memory data is compared with the test data written into the row of memory cells bit by bit to determine the test results of the row of memory cells. In this manner, it is possible to determine whether the read-write performance of each row of memory cells is normal in order of rows.

In an alternative implementation, the test data may further be written into each column of memory cells of the memory chip, and the memory data is read from each column of memory cells of the memory chip, by traversing the memory cells. For example, the test data may be written into each column of memory cells of the memory chip in order of columns of an array in which the memory cells are positioned, such as, 1-bit binary data is sequentially written into each memory cell in each column, until the test data is written into each memory cell of the memory chip.

Further, in an alternative implementation, the method for testing the memory chip may further include the following operations.

During a column detection period, the test data is written into any column of memory cells of the memory chip, and the memory data is read from the any column of memory cells.

Test results of the column of memory cells are determined based on the test data written into the any column of memory cells and the memory data read from the any column of memory cells.

The column detection period refers to time duration required for testing a column of memory cells. When the test data is written in order of columns, during the column detection period, the test data may be written into any column of memory cells of the memory chip, and after writing the data into the any column of memory cells, the data stored in the any column of memory cells is read to obtain the memory data, and the memory data is compared with the test data written into the any column of memory cells bit by bit to determine the test results of the any column of memory cells. In this manner, it is possible to determine whether the read-write performance of each column of memory cells is normal in order of columns.

Actually, a data length of the test data may be any length when the test data is written into memory cells of a memory chip in order of rows or columns. For example, in an alternative implementation, a number of rows or columns of the memory cells of the memory chip may be greater than a number of data bits of the test data. Taking writing by row as an example, assuming that each row of a memory chip has N memory cells, the number of data bits of the test data is M, M and N are positive integers, and N>M, when the test data is written into each row of memory cells in a left-to-right or right-to-left manner, each memory cell stores 1-bit binary data, after writing data into the (M)th memory cell, the (M+1)th memory cell is taking as the first memory cell in the row and the test data is re-written in sequential, until the data written of all memory cells in the row is completed. Assuming that the number M of data bits of the test data is larger than the number N of memory cells in each row, the test data may be written into the first row of memory cells in a left-to-right or right-to-left manner, each memory cell stores 1-bit binary data, until the binary data is written into all memory cells in the row. When the test data is written into the next row of memory cells, the test data may be rewritten from the first memory cell of the row. In this manner, the data of data bits greater than the number of rows of memory cells in the test data will not be written into the memory cells, that is, only partial data bits equal to the number of rows of memory cells in the test data will be written into each row of memory cells of the memory chip. Assuming that the number M of bits of the test data is equal to the number N of memory cells in each row, it is only necessary to sequentially write each binary sequence into each memory cell in the same row.

Further, in an alternative implementation, when the number of rows or columns of the memory cells of the memory chip is greater than the number of data bits of the test data, the number of rows or columns of the memory cells of the memory chip may be an integer multiple of the number of data bits of the test data. For example, when test data is written in order of rows, the test data may be sequentially written into each row of memory cells, so that a row of memory cells stores multiple sets of test data, and each set of test data is sequentially stored in successive memory cells.

Further, in an alternative implementation, to test the read-write performance of each memory cell comprehensively, all memory cells of the memory chip may be set to 0 before writing the test data into the memory cells of the memory chip. That is, before writing the test data into the memory cells of the memory chip, an all-0 binary sequence may be written into all memory cells of the memory chip, i.e., 1-bit binary data “0” may be written into each memory cell of the memory chip, until the data writing of all memory cells of the memory chip is completed.

Further, in an alternative implementation, after setting all memory cells of a memory chip to 0, the data written into each memory cell may be read, and corresponding memory data is obtained, and whether the data of each data bit of the memory data is “0” is judged to determine whether the data written into each memory cell is the same as the data read from the memory cell. If the data written into each memory cell is the same as the data read from the memory cell, the read-write performance of the memory cell with respect to “0” is normal. Otherwise, the read-write function of the memory cell with respect to “0” is abnormal. Further, due to the fact that the data written into each memory cell is “0”, when reading the data written into each memory cell, the data written into each memory cell may be read in any direction, or the data written into each memory cell may be traversed in a random manner, which is not specifically limited herein.

In this manner, before writing the test data, it is determined whether the read-write performance of each memory cell with respect to data “0” is abnormal, so as to perform a preliminary test on each memory cell, so that, when the test data is written and read, it can quickly determine whether the read-write performance of each memory cell with respect to data “1” is normal without judging a read-write result of each memory cell with respect to the data “0”, thereby improving the accuracy and comprehensiveness of testing the memory chip, and improving the efficiency of testing the memory chip.

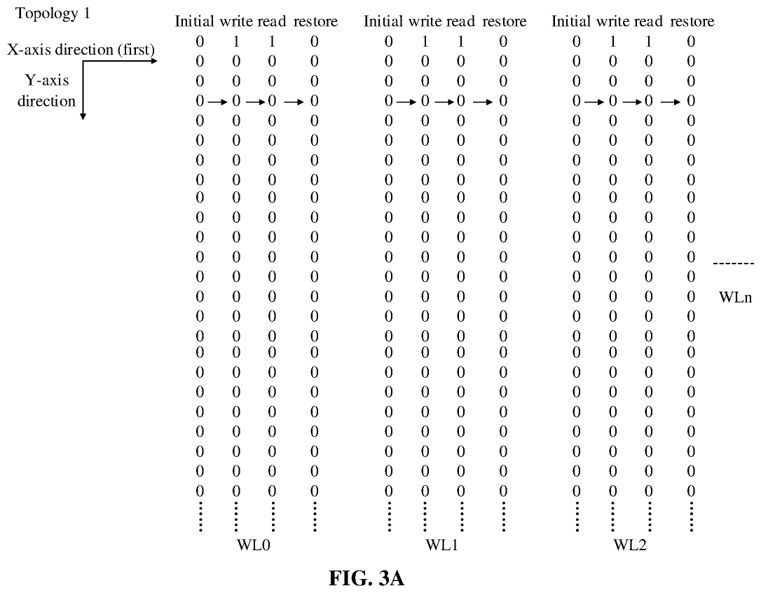

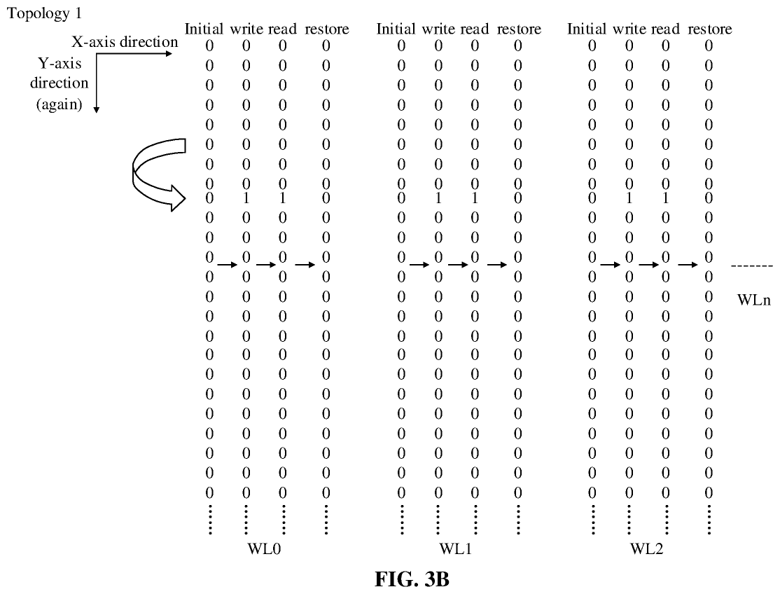

In an alternative implementation, the memory cells of the memory chip may be tested in order of rows and columns simultaneously. As shown in FIG. 3A, each data topology shown in FIG. 2 may be written into memory cells of the memory chip, and a test result corresponding to each data topology is determined based on the memory data read after writing. Specifically, taking topology 1 as an example, assuming that the number of memory cells in each row and each column of the memory chip is 8, an all-0 sequence may be written into all memory cells of the memory chip first, so that each memory cell stores data “0” in an initial state. Then, the topology 1, i.e., “10000000” is written into the first row of memory cells corresponding to each word line, i.e., WL0, WL1, WL2, WLn of the memory chip in an X-axis direction. After writing, the memory data of the first row of memory cells is read, and then the memory data of the first row is compared with the written test data to determine a test result of the first row of memory cells. When another row of memory cells is tested, the data of the first row of memory cells may be set to 0, then the test data is written into the row to be tested of memory cells in the same manner, and then the memory data of the row of memory cells is read and is compared with the test data to determine a test result of the row of memory cells. In this manner, the test of each row of memory cells is completed. Further, as shown in FIG. 3B, the all-0 sequence may be written into all memory cells of the memory chip first, so that each memory cell stores data “0” in an initial state. Then, the topology 1, i.e., “10000000” is written into each column of memory cells (e.g., the second column of memory cells as shown in FIG. 3B) corresponding to each word line, i.e., WL0, WL1, WL2, WLn of the memory chip from another row in the Y-axis direction. After writing, the memory data of the second column of memory cells is read, and then the memory data of the second column of memory cells is compared with the written test data to determine a test result of the second column of memory cells. When each column of memory cells is tested according to this manner, the memory data of each column of memory cells, except the currently tested column, is 0. The test of each column of memory cells of the memory chip is completed with the topology 1 according to the above manner, and then the data writing and reading of topology 2 to topology 8 in the memory chip are repeated, and each corresponding test result is determined.

In this manner, the read-write performance of each row and column of memory cells may be determined from both rows and column directions, thereby completing the test of the memory chip comprehensively.

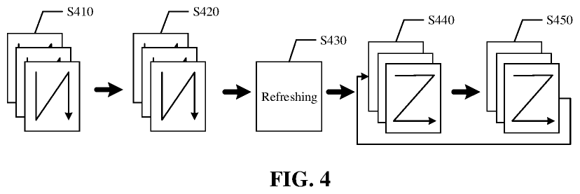

In an exemplary implementation, a memory chip may include multiple memory pages, each of which may include a same number or different numbers of memory cells. During test, the test data may be written into the memory cells in each memory page, and the memory data of the memory cells in each memory page is read, and the memory data is compared with the written test data to determine a corresponding test result of each memory cell in each memory page of the memory chip. For example, in an alternative implementation, as shown in FIG. 4, a memory chip may be tested according to the following operations S410 to S450.

At S410, an all-0 sequence is written into each memory cell in each memory page of a memory chip.

Specifically, the all-0 sequence may be written, in order of rows or columns, into each row of memory cells or each column of memory cells in each memory page of the memory chip. For example, an all-0 sequence may be written into each column of memory cells in each memory page of the memory chip, so that 1-bit binary data “0” is written into each memory cell.

At S420, the all-0 sequence written into each memory cell in each memory page is read sequentially to obtain memory data, and comparing the memory data with the all-0 sequence to determine a test result of the memory chip with respect to “0”.

Specifically, the data written into each memory cell in each memory page may be read according to a direction in which the all-0 sequence is written. For example, the data written into each column of memory cells may be read based on the sequence in which the all-0 data sequence is written, to obtain the memory data corresponding to the column of memory cells. Then, the all-0 sequence is compared with the memory data, to determine whether data of each data bit is the same as the data written into each memory cell, and to determine whether the read-write function of each memory cell in the column is normal, so as to obtain the test result of the column of memory cells, and to determine the test result of each column of memory cells in each memory page in the same manner, and to obtain the test result of the memory chip with respect to “0”.

At S430, after completing the reading operation of the memory cell, the memory cell is refreshed and “0” is written back into the memory cell.

To keep the data “0” stored in each memory cell and avoid the state change of some memory cell and the influence thereof on the test results of other memory cells, each memory cell may be refreshed after completing the reading operation of each memory cell in each memory page. Specifically, each memory cell may be refreshed in the following manner, that is, when the read operation of the all-0 sequence written into each row or column of memory cells in the memory page is completed, each row or column of memory cells is refreshed and “0” is written back into each memory cell.

In this manner, after the read operation of each row or column of memory cells and each memory cell in each memory page is completed, each row or column of memory cells and each memory cell in each memory page are refreshed to ensure that the data of each memory cell in each memory page is continuously and stably stored.

At S440, the test data is written into each memory cell in each memory page of the memory chip based on a target write time of the memory chip.

The test data may include multiple different binary sequences. When the test data is written, a clock signal matched with the target write time may be generated by a logic control circuit, and a binary sequence in the test data may be written into each row of memory cells or each column of memory cells in each memory page of the memory chip in order of rows or columns. The direction in which second test data is written may be the same as or different from the direction in which the first test data, i.e., all-0 data is written firstly.

Taking writing by rows as an example, a binary sequence may be written into each row of memory cells or each column of memory cells in each memory page of a memory chip according to the direction in which test data is written, until 1-bit data of the binary sequence is written into each memory cell in each memory page.

At S450, the memory data is read from the memory cell based on a target read time of the memory chip, and a second test result of the memory chip is determined based on the test data and the memory data.

To determine the performance of each memory cell, the memory chip may be set to be in a read state by the logic control circuit, a clock signal matched with the target read time is generated, the binary sequence written into each memory cell in each memory page is read in order of rows or columns to obtain a set of memory data, and then the test result of the memory chip with respect to the binary sequence is determined by comparing the set of memory data and the corresponding binary sequence.

After completing the writing and reading data of a binary sequence in the test data for each memory cell in each memory page, the operations S440 to S450 may be performed again, and then another binary sequence in the test data is written into each memory page of the memory chip, and the binary sequence written into the memory chip is read, new memory data read is compared with the corresponding binary sequence, and a test result of the memory chip with respect to the corresponding binary sequence is determined, until the writing and reading of the data of each binary sequence in the test data for each memory cell in each memory page is completed, and a corresponding test result is determined.

Finally, the read-write performance of each memory cell in each memory page of the memory chip when different binary sequences are stored is determined based on each test result, thereby completing testing the memory chip.

To sum up, according to the method for testing the memory chip in the exemplary implementations, the test data may be written into the memory cells of the memory chip based on the target write time of the memory chip, and the memory data is read from the memory cell based on the target read time of the memory chip; and the test result of the memory chip is determined based on the test data and the memory data. Due to the fact that the target write time of the memory chip is less than the standard write time of the memory chip, and the target read time is less than the standard read time of the memory chip, the time for testing the memory chip can be shortened, the memory cell with a read-write error can be quickly detected, and the efficiency of testing the memory chip is greatly improved.

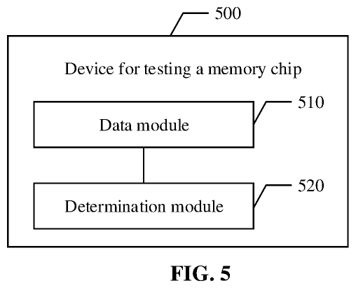

An exemplary implementation further provides a device for testing a memory chip. As shown in FIG. 5, the device 500 for testing the memory chip may include a data module 510 and a determination module 520. The data module may be configured to write test data into memory cells of the memory chip based on a target write time of the memory chip, and read memory data from the memory cell based on a target read time of the memory chip; and the determination module may be configured to determine a test result of the memory chip based on the test data and the memory data. The target write time is less than a standard write time of the memory chip, and the target read time is less than a standard read time of the memory chip.

In an exemplary implementation of the disclosure, the data module 510 may be configured to write the test data into each row of memory cells of a memory chip, and read the memory data from each row of memory cells of the memory chip, by traversing the memory cells.

In an exemplary implementation of the disclosure, the data module 510 may further be configured to write the test data into any row of memory cells of the memory chip, and read the memory data from the any row of memory cells of the memory chip, during a row detection period. The determination module 520 may be configured to determine test results of the any row of memory cells based on the test data written into the any row of memory cells and the memory data read from the any row of memory cells.

In an exemplary implementation of the disclosure, the data module 510 may further be configured to write test data into each column of memory cells of the memory chip, and read the memory data from each column of memory cells of the memory chip, by traversing the memory cells.

In an exemplary implementation of the disclosure, the data module 510 may further be configured to write test data into each memory cell in any column of memory cells of the memory chip, and read the memory data from each memory cell in any column of memory cells of the memory chip during a column detection period; and the determination module 520 may be configured to determine a test result of each memory cell in any column of memory cells based on the test data written into the any column of memory cells and the memory data read from the any column of memory cells, during the column detection period.

In an exemplary implementation of the disclosure, the test data includes multiple binary sequences with equal data bits, and the test data has different data topologies.

In an exemplary implementation of the disclosure, the number of rows or columns of the memory cells of the memory chip is greater than the number of data bits of the test data.

In an exemplary implementation of the disclosure, the number of rows or columns of the memory cells of the memory chip is an integer multiple of the number of data bits of test data.

In an exemplary implementation of the disclosure, the test data includes any of the multiple different binary sequences.

In an exemplary implementation of the disclosure, the determination module 520 may further be configured to compare the memory data with the test data to obtain the test result indicating whether a read-write error occurs in each of the memory cells of the memory chip and indicating a number of data bits with the read-write error.

In an exemplary implementation of the disclosure, the data module 510 may further be configured to set all of the memory cells of the memory chip to 0 before writing the test data into each of the multiple memory cells of the memory chip.

In an exemplary implementation of the disclosure, the data module 510 may further be configured to set all of the memory cells of the memory chip after determining the test result of the memory chip.

In an exemplary implementation of the disclosure, the data module 510 may further be configured to determine multiple data topologies in the test data in the following manner, that is, the initial test data is traversed by taken any of data bits in initial test data as a conversion bit, the initial test data is traversed, and data at the traversed conversion bit is converting into inverted data to obtain a conversed sequence, until all the data bits in the initial test data are traversed, and the obtained multiple conversed sequences are determined as the multiple data topologies. The initial test data is an all-0 sequence of arbitrary length.

The specific details of each module of the device is described in detail in the embodiments of the method, and the details of the solution of the device which are not disclosed may be understood with reference to those of the embodiments of the method, which will not be repeated herein.

Those skilled in the art should understand that, an aspect of the disclosure may be implemented as a system, a method or a program product. Therefore, an aspect of the disclosure may be specifically implemented as hardware alone, software alone (including firmware, microcode, etc.), or a combination of hardware and software, which may be collectively referred to herein as “circuit”, “module”, or “system”.

An exemplary implementation of the disclosure further provides a computer-readable storage medium, having a program product stored thereon, the program product is configured to implement the method for testing the memory chip as described above in the disclosure. In some possible implementations, an aspect of the disclosure may further be implemented as a program product including a program code. The program code is configured to cause a terminal device to implement the method for testing the memory chip in the exemplary implementation of the disclosure, when the program product runs in the terminal device.

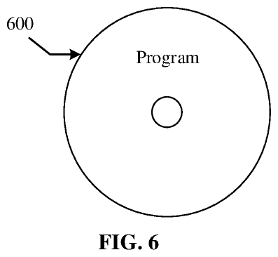

FIG. 6 illustrates a schematic diagram of a program product 600 configured to implement the method for testing the memory chip in the exemplary implementations of the disclosure. The program product may adopt a portable compact disk read-only memory (CD-ROM) and include a program code, and may run in a terminal device such as a personal computer. However, the program product according to the disclosure is not limited thereto, and in this specification, the readable storage medium may be any tangible medium including or storing a program which may be used by or in combination with an instruction-executable system, device, or apparatus.

The program product 600 may adopt any combination of one or more readable media. The readable medium may be a readable signal medium or a readable storage medium. For example, a readable storage medium may be, but is not limited to, an electrical, magnetic, optical, electromagnetic, infrared, or semiconductor system, device or apparatus, or any combination thereof. More specifically, the readable storage medium may be an electrical connection having one or more conductors, portable disk, hard disk, random access memory (RAM), read-only memory (ROM), erasable programmable read-only memory (EPROM) or flash memory, optical fiber, portable compact disk read-only memory (portable CD-ROM), optical memory device, magnetic memory device, or any appropriate combination thereof.

The computer-readable signal medium may include a data signal transmitted in a baseband or as part of a carrier wave, in which a readable program code is carried. The transmitted data signal may be in different forms, including but not limited to: an electromagnetic signal, optical signal, or any suitable combination thereof. The readable signal medium may further be any readable medium other than the readable storage medium and the readable signal medium may be configured to send, propagate or transmit a program used by or in combination with an instruction-executable system, device or apparatus.

The program code in the readable medium may be transmitted in any suitable medium, including but not limited to a wireless medium, wired medium, optical cable, radio frequency (RF) etc., or any appropriate combination thereof.

The program code configured to implement the operations of the disclosure may be written with any combination of one or more program design languages, including an object-oriented program design language, such as Java, C++, etc., and an conventional procedural program design language, such as the “C” language or a similar program design language. The program code may be entirely executed by a user computing device, partially executed by a user device, executed as an independent software package, partially executed by a user computing device and partially executed by a remote computing device, or entirely executed by a remote computing device or server. When it comes to the remote computing device, the remote computing device may be connected to the user computing device through any kind of network, including Local Area Network (LAN) or Wide Area Network (WAN), or may be connected to an external computing device (e.g. via the Internet through an Internet service provider).

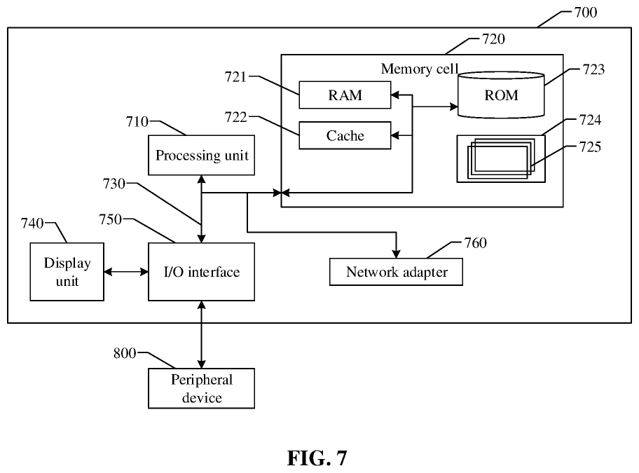

An exemplary implementation of the disclosure further provides an electronic device capable of implementing a method for testing a memory chip. The electronic device 700 in the exemplary implementation of the disclosure will be described below with reference to FIG. 7. The electronic device 700 shown in FIG. 7 is merely illustrative and is not intended to limit the functionality and use of the disclosed implementation.

As shown in FIG. 7, the electronic device 700 may be embodied as a general-purpose computing device. Components of the electronic device 700 may include, but are not limited to, at least one processing unit 710, at least one memory cell 720, a bus 730 connecting different system components (including the memory cell 720 and the processing unit 710), and a display unit 740.

The memory cell 720 is configured to store program code that can be executed by the processing unit 710 to cause the processing unit 710 to perform the method for testing the memory chip in the exemplary implementations of the disclosure. For example, the processing unit 710 may perform the method operations shown in FIG. 1 and FIG. 4 and the like.

The memory cell 720 may include a readable medium in the form of a volatile memory, such as a random access memory (RAM) 721 and/or a cache 722 and may further include a read-only memory (ROM) 723.

The memory cell 720 may further include a program/utility 724 having a set of (at least one) program modules 725, including, but not limited to, an operating system, one or more application programs, another program module, and program data, each or some combination of which may include an implementation of a network environment.

The bus 730 may include one or more of multiple types of bus structures, including a memory cell bus or a memory cell controller, a peripheral bus, an accelerated graphics port (AGP), a processing unit, or a local bus using any of multiple bus structures.

The electronic device 700 may further communicate with one or more peripheral devices 800 (e.g. keyboards, pointer devices, Bluetooth devices, etc.), and may further communicate with one or more devices which enable a user to interact with the electronic device 700, and/or with any device (e.g. a router, modem, etc.) which enables the electronic device 700 to communicate with one or more other computing devices. The communication may be implemented through an input/output (I/O) interface 750. Further, the electronic device 700 may further communicate with one or more networks (e.g. a local area network (LAN), a wide area network (WAN) and/or a public network, such as Internet) through a network adapter 760. As shown in FIG. 7, the network adapter 760 communicates with another module of the electronic device 700 through the bus 730. It should be understood that, although not shown, other hardware and/or software modules, including, but not limited to, microcode, device drivers, redundancy processing units, external disk drive arrays, RAID systems, tape drives, and data backup storage systems, etc., may be used in combination with the electronic device 700.

It should be noted that, although multiple modules or units of the device configured to perform the actions are mentioned in the foregoing detailed description, this division of the modules or units is not mandatory. Actually, in some exemplary implementations of the disclosure, the features and functions of two or more modules or units described above may be embodied in one module or unit. Conversely, the features and functions of one module or unit described above may further be divided into multiple modules or units to be embodied.

Further, the drawings only illustrate schematic diagrams of processes of the method in the exemplary implementations of the disclosure and are not intended to be limiting. It should be understood that, the processes shown in the drawings do not indicate or limit the temporal order of the processes. In addition, it should be further understood that the processes may be performed synchronously or asynchronously, e.g., in multiple modules.

It should be understood by those skilled in the art from the foregoing description of the implementations that the exemplary implementations described herein may be implemented by software or in combination with required hardware. Therefore, the technical solution of the exemplary implementations of the disclosure may be embodied as a software product. The software product may be stored in a non-volatile or non-transitory storage medium (which may be a CD-ROM, a USB flash disk, a portable hard disk, etc.) or on a network, and the software product includes instructions to cause a computing device (which may be a personal computer, a server, a terminal device, or a network device, etc.) to perform the method in the exemplary implementations of the disclosure.

In some examples, the terms “module” and “unit” and the like in the device as shown in FIG. 5 may be implemented by one or more hardware circuits/sub-circuits and/or one or more processors. In some examples, a module or unit may include one or more circuits with or without stored code or instructions. The module or unit may include one or more components that are directly or indirectly connected. These components may or may not be physically attached to, or located adjacent to, one another.

Other implementations of the disclosure may be readily derived from the specification and through practicing the implementations herein by those skilled in the art. The disclosure is intended to cover any variations, uses, or adaptations of the disclosure that follow the general principles of the disclosure and include common sense or conventional techniques in the art which are not disclosed in the disclosure. The specification and implementations are only illustrative and the scope and spirit of the disclosure are defined by the claims.

1. A method for testing a memory chip, comprising:
writing test data into memory cells of the memory chip based on a target write time of the memory chip, and reading memory data from the memory cell based on a target read time of the memory chip; and
determining a test result of the memory chip based on the test data and the memory data,
wherein the test data comprises a plurality of different binary sequences, only one of data bits in each binary sequence is 1, the target write time is less than a standard write time of the memory chip, and the target read time is less than a standard read time of the memory chip.

2. The method of claim 1, further comprising:
writing the test data into each row of memory cells of the memory chip and reading the memory data from each row of memory cells of the memory chip, by traversing the memory cells.

3. The method of claim 2, further comprising:
during a row detection period, writing the test data into any row of memory cells of the memory chip, and reading the memory data from the any row of memory cells; and
determining test results of the any row of memory cells based on the test data written into the any row of memory cells and the memory data read from the any row of memory cells.

4. The method of claim 1, further comprising:
writing the test data into each column of memory cells of the memory chip and reading the memory data from each column of memory cells of the memory chip, by traversing the memory cells.

5. The method of claim 4, further comprising:
during a column detection period, writing the test data into any column of memory cells of the memory chip, and reading the memory data from the any column of memory cells; and
determining test results of the column of memory cells based on the test data written into the any column of memory cells and the memory data read from the any column of memory cells.

6. The method of claim 1, wherein the test data comprises the binary sequences with equal data bits, and the test data has a plurality of data topologies that are different from each other.

7. The method of claim 2, wherein a number of rows of the memory cells of the memory chip is greater than a number of data bits of the test data.

8. The method of claim 2, wherein a number of rows of the memory cells of the memory chip is an integer multiple of a number of data bits of the test data.

9. The method of claim 4, wherein a number of columns of the memory cells of the memory chip is greater than a number of data bits of the test data.

10. The method of claim 4, wherein a number of columns of the memory cells of the memory chip is an integer multiple of a number of data bits of the test data.

11. The method of claim 1, wherein determining the test result of the memory chip based on the test data and the memory data comprises:
comparing the memory data with the test data to obtain the test result, wherein the test result indicates whether a read-write error occurs in each of the memory cells of the memory chip and indicates a number of data bits with the read-write error.

12. The method of claim 1, further comprising: before writing the test data into the memory cells of the memory chip,
setting all the memory cells of the memory chip to 0.

13. The method of claim 1, further comprising: after determining the test result of the memory chip,
setting all the memory cells of the memory chip to 0.

14. The method of claim 6, wherein the plurality of data topologies in the test data are determined by:
traversing initial test data by taking any of data bits in the initial test data as a conversion bit, and converting, by inverting data at the traversed conversion bit, the data at the traversed conversion bit into the inverted data to obtain a conversed sequence, until all the data bits in the initial test data are traversed, and determining a plurality of obtained conversed sequences as the plurality of data topologies,
wherein the initial test data is an all-zero sequence with any length.

15. A device for testing a memory chip, comprising:
a read-write circuit configured to write test data into memory cells of the memory chip based on a target write time of the memory chip, and read memory data from the memory cell based on a target read time of the memory chip; and
a determination circuit, configured to determine a test result of the memory chip based on the test data and the memory data,
wherein the test data comprises a plurality of different binary sequences, only one of data bits in each binary sequence is 1, the target write time is less than a standard write time of the memory chip, and the target read time is less than a standard read time of the memory chip.

16. A non-transitory computer-readable storage medium, having a computer program stored thereon, wherein the computer program is configured to perform the method of claim 1, when executed by a processor.

17. An electronic device, comprising:
a processor; and
a memory, configured to store processor-executable instructions,
wherein the processor is configured to perform the method of claim 1 by executing the processor-executable instructions.
